(19) United States
(12) Patent Application Publication
(10) Pub. No.: US 2011/0249480 A1
(43) Pub. Date: Oct. 13, 2011

(54) NONVOLATILE MEMORY DEVICE

(76) Inventor: Ho Youb Cho, Seoul (KR)

(21) Appl. No.: 13/085,028

(22) Filed: Apr. 12, 2011

(30) Foreign Application Priority Data
Apr. 13, 2010 (KR) 10-2010-0033718

(51) Int. Cl. G11C 15/00; G11C 29/04

(52) U.S. Cl. 365/49.1; 365/189.07; 365/200

(57) ABSTRACT

Disclosed is a nonvolatile memory device including a memory cell array including main and redundant memory cells, content addressable memory cells configured to store a defective column address corresponding to a defective memory cell among the main cells, and a repair controller configured to compare the defective column address with an input address to generate a matching control signal and generate a redundancy check-enable signal when the defective column address is inputted as the input address and configured to generate a repair control signal in response to the matching control signal and the redundancy check-enable signal.

### CROSS-REFERENCE TO RELATED APPLICATIONS

The present application claims priority under 35 U.S.C 119(a) to Korean Application No. 10-2010-0033718, filed on Apr. 13, 2010, in the Korean Intellectual Property Office, which is incorporated by reference in its entirety.

### BACKGROUND

1. Technical Field

Exemplary embodiments of the present invention relate to nonvolatile memory devices.

2. Related Art

Nonvolatile memories, as a class of semiconductor memories, are employing the operational functions of erasing and programming data. In particular, electrically erasable and programmable nonvolatile memories, e.g., EEPROM, flash memory, etc., achieve the erasing and programming operations by utilizing the Fowler-Nordheim (F-N) tunneling effect and hot electron injection, respectively.

A nonvolatile memory device is ordinarily designed to pass through a repair process when there is a defect in a memory cell coupled with a column line. For repairing the defect in the memory cell, a column address assigned to the defective memory cell (hereafter referred to as a defective column address) is sought and stored in content addressable memory (CAM) cells.

Those CAM cells are usually formed by an additional storage section or a part of memory cells. At an initial operation of the nonvolatile memory device, information on the defective column address is loaded and latched from the CAM cells, and then compared with an address that is input for a subsequent programming or reading operation. If it determines that there is an input of the defective column address, a redundancy column is selected to replace a column corresponding to the defective column address.

For this function, a nonvolatile memory device is designed to include a latch circuit for holding a defective column address, and a comparing circuit for providing a repair control signal by comparing an input address with the defective column address that is held at the latch circuit.

### SUMMARY

Accordingly, exemplary embodiments of the present invention are directed to a nonvolatile memory device improvable in area by reducing the number of circuit elements to latch and compare a defective column address that is allocated for a redundancy operation.

In an exemplary embodiment, a nonvolatile memory device may include a memory cell array including main and redundant memory cells; content addressable memory cells configured to store a defective column address corresponding to a defective memory cell among the main cells; and a repair controller configured to compare the defective column address with an input address to generate a matching control signal and generate a redundancy check-enable signal when the defective column address is inputted as the input address and configured to generate a repair control signal in response to the matching control signal and the redundancy check-enable signal.

The repair controller may include a plurality of address latches configured to store the defective column address; a plurality of comparators configured to compare the defective column address and the input address to generate the matching control signal and the redundancy check-enable signal; and a repair signal generator configured to generate the repair control signal in response to the matching control signal and the redundancy check-enable signal. Each address latch may include a plurality of latch units configured to store the defective column address by bit; and each comparator may include a plurality of comparator units configured to output the matching control signal by comparing the input address with the defective column address provided respectively from the latch units.

Each comparator unit may output the matching control signal with a first logic level if the defective column address of the latch unit has the same logic level as the input address.

Each comparator unit may include first and second switches configured to selectively output the input address and an inversion signal of the input address as the matching control signal according to the defective column address of the latch unit.

The repair signal generator may output the repair control signal, which indicates that the input address is the defective column address, if the matching control signal and the redundancy check-enable signal are the first logic level.

The repair signal generator may include: one or more logical combination gates configured to conduct a NAND operation on the matching control signal and the redundancy check-enable signal; and a logical combination circuit configured to logically combine output signals of the logical combination gates to generate the repair control signal.

The logical combination circuit may include: a NOR gate configured to conduct a NOR operation on the output signals of the logical combination gates; and an inverter configured to output the repair control signal from an output signal of the NOR gate.

The main or redundant cells may be selected in response to the repair control signal.

In another exemplary embodiment, a nonvolatile memory device may include a memory cell array comprising main and redundant cells; a fuse circuit block configured to store a defective column address that is assigned to a defective cell of the main cells; a plurality of comparators configured to compare the defective column address with an input address inputted by an operation command, and configured to output a matching control signal corresponding to a compared result and output a redundancy check-enable signal indicating that the defective column address is inputted as the input address; and a repair signal generator configured to output a repair control signal in response to the matching control signal and the redundancy check-enable signal.

The comparator may output the matching control signal with a first logic level if the defective column address has the same logic level as the input address.

The comparator may include first and second switches configured to selectively output a signal the input address and an inversion signal of the input address as the matching control signal according to the defective column address.

The repair signal generator may output the repair control signal, which indicates that the input address is the defective column address, if the matching control signal and the redundancy check-enable signal are the first logic level.

The repair signal generator may include: one or more logical combination gates configured to conduct a NAND operation on the matching control signal and the redundancy check-enable signal; and a logical combination circuit configured to logically combine output signals of the logical combination gates to generate the repair control signal.

The logical combination circuit may include: a NOR gate configured to conduct a NOR operation on the output signals of the logical combination gates; and an inverter configured to output the repair control signal from an output signal of the NOR gate.

According to the present invention, a nonvolatile memory device may be improved in area and performance by reducing the number of circuit elements that are formed in a latch circuit for temporarily holding a defective column address, and formed in a comparing circuit for providing a repair control signal by comparing the defective column address with an input address.

A further understanding of the nature and advantages of the present invention herein may be realized by reference to the remaining specification and the attached drawings.

### BRIEF DESCRIPTION OF THE DRAWINGS

The present invention is illustrated by way of example, and not by way of limitation, in the figures of the accompanying drawings, in which like reference numbers refer to similar elements and in which:

FIG. 1 illustrates a nonvolatile memory device;

FIG. 2A illustrates an exemplary embodiment of a repair controller shown in FIG. 1;

FIG. 2B illustrates a latch unit of a redundancy info-latch block shown in FIG. 2A;

FIG. 2C illustrates a redundancy circuit of an address comparator shown in FIG. 2B;

FIGS. 3A and 3B are timing diagrams showing an address comparison operation according to the embodiment of FIG. 2A;

FIG. 4A illustrates a repair controller according to another exemplary embodiment of the present invention;

FIG. 4B illustrates a latch comparator of a first latch comparator block shown in FIG. 4A;

FIG. 4C illustrates a repair signal generator shown in FIG. 4A;

FIG. 4D illustrates another exemplary embodiment of the latch comparator belonging to the first latch comparator block shown in FIG. 4A;

FIG. 4E illustrates another exemplary embodiment of the latch comparator belonging to the first latch comparator block shown in FIG. 4A; and

FIGS. 5A and 5B are timing diagrams showing output patterns of a repair control signal according to the exemplary embodiments shown in FIGS. 4A to 4D.

### DESCRIPTION OF EMBODIMENTS

Hereinafter, various exemplary embodiments will now be described more fully with reference to the accompanying drawings. However, specific structural and functional details disclosed herein are merely representative for purposes of describing exemplary embodiments of the present invention.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Further, it will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the invention. As used herein, the term “and/or” includes any and all combinations of one or more of the associated listed items. Also it should be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In order to more specifically describe exemplary embodiments, various aspects will be hereinafter described in detail with reference to the accompanying drawings.

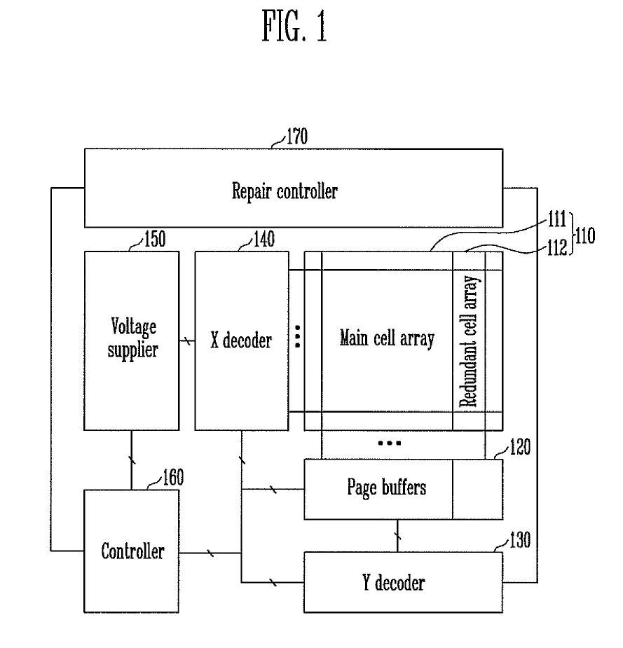

FIG. 1 depicts a nonvolatile memory device.

Referring to FIG. 1, the nonvolatile memory device 100 is organized by including a memory cell array 110, a page buffer block 120, a Y-decoder 130, an X-decoder 130, a voltage supplier 150, a controller 160 and a repair controller 170.

The memory cell array 110 contains a main cell array 111 and a redundant cell array 112. The main cell array 111 and the redundant cell array 112 include a plurality of memory cells electrically connected through bit and word lines. The nonvolatile memory device 100 may designate a certain memory cell by selecting a bit and word line when programming data.

If there is a defective memory cell in the main cell array 111, a repairing operation is conducted by designating a column address of a bit line, which is coupled to the defective memory cell, as a defective column address and replacing the defective memory cell with a memory cell of the redundant cell array 112.

Some memory cells of the main and redundant cell arrays 111 and 112 are defined as content addressable memory (CAM) cells to store defective column addresses or optional information used for operations of the nonvolatile memory device.

The page buffer block 120 includes a plurality of page buffers each coupled to one or more bit lines. Each page buffer functions to latch data that is to be stored in a selected memory cell, and to read data from the selected memory cell and store it therein.

The Y-decoder 130 provides data input/output paths to the page buffers in correspondence with an input address. During the repairing operation, the Y-decoder 130 connects a page buffer, which is coupled to the main cell array 111, with one of page buffers coupled to the redundant cell array 112 in compliance with a control signal.

The X-decoder 140 selectively connects a word line of the memory cell array 110 to a global word line for supplying an operation voltage in accordance with the input address.

The voltage supplier 150 generates operation voltages for programming, reading and erasing operations, and then provides the operation voltages to the global word line. The controller 160 outputs control signals for the programming, reading and erasing operations.

The repair controller 170 functions to latch a defective column address that is stored in the CAM cells and output a repair control signal by comparing the defective column address with an input address received for programming or reading data.

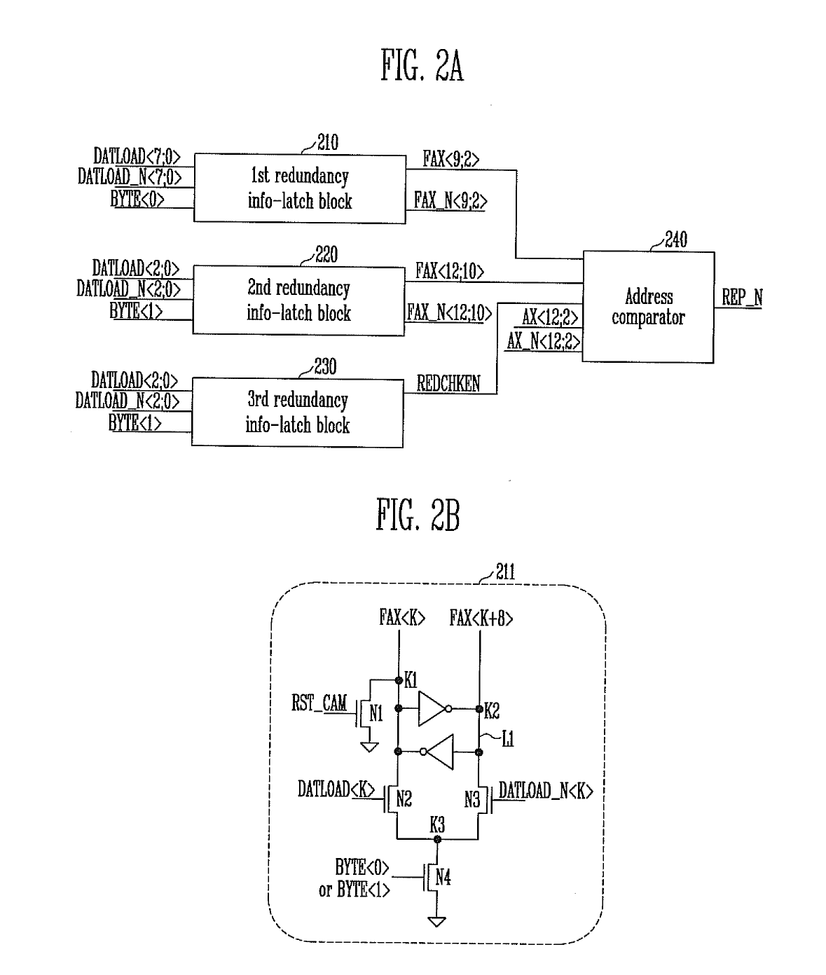

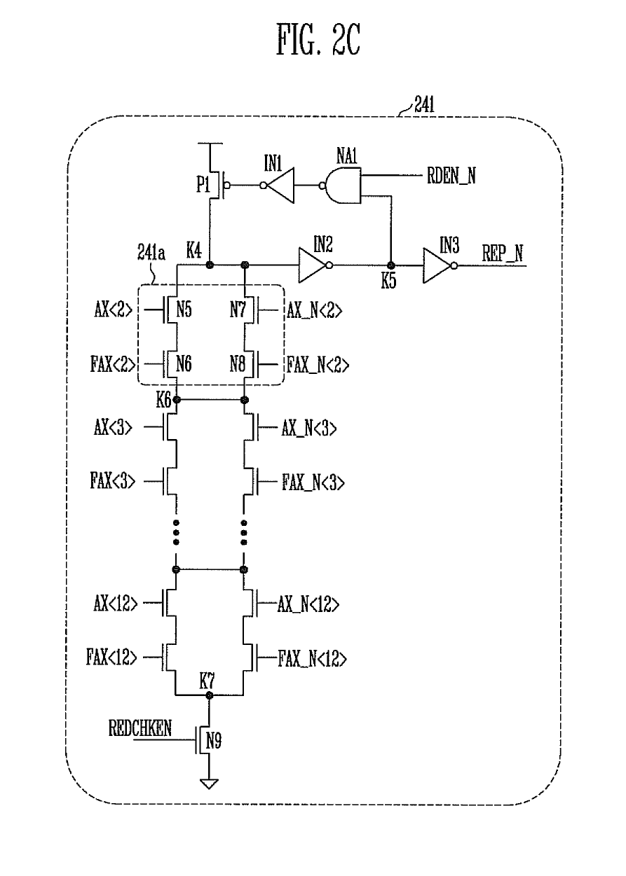

FIG. 2A depicts an exemplary embodiment of the repair controller shown in FIG. 1.

Referring to FIG. 2, the repair controller 170 is organized by including first to third redundancy info-latch blocks 210-230, and an address comparator 240. The first to third redundancy info-latch blocks 210-230 and the address comparator 240 may be disposed to each column address that is defective.

The first to third redundancy info-latch blocks 210-230 each include units of latch circuits for holding a defective column address according to first to eighth data bits DATLOAD<7:0> in response to first and second control signals BYTE<0> and BYTE<1>. Inverse data bits of the first to eighth data bits DATLOAD<7:0> are arranged in ninth to sixteenth data bits DATLOAD_N<7:0>.

The first and second redundancy info-latch blocks 210 and 220 output first to eleventh defective column address bits FAX<12:2>. The third redundancy info-latch block 230 outputs a redundancy check-enable signal REDCHKEN. Inverse data bits of the first to eleventh defective column address bits FAX<12:2> are arranged in twelfth to twenty-second defective column address bits FAX_N<12:2>.

The first to eleventh defective column address bits FAX<12:2> correspond to a column address of a bit line where a defect is generated. In other words, each defective bit line is assigned to have its own value of the first to eleventh defective column address bits FAX<12:2>.

The address comparator 240 outputs a repair control signal REP_N by comparing first to eleventh input address bits AX<12:2>and twelfth to twenty-second input address bits AX_N<12:2> with the first to twenty-second defective column address bits FAX<12:2> and FAX_N<12:2> under control of the redundancy check-enable signal REDCHKEN.

The first and second redundancy info-latch blocks 210 and 220 each include a plurality of units of latch circuits to store their defective column address bits by one bit. Meanwhile, the third redundancy info-latch block 230 outputs the redundancy check-enable signal REDCHKEN for determining to check up repair information.

The address comparator 240 is formed with redundancy circuits for outputting the repair control signal REP_N by comparing the first to twenty-second defective column address bits FAX<12:2> and FAX_N<12:2> with the first to twenty-second address bits AX<12:2> and AX_N<12:2>.

FIG. 2B depicts a latch unit of the redundancy info-latch block shown in FIG. 2A. FIG. 2B representatively shows one of the latch units belonging to the first and second redundancy info-latch blocks 210 and 220.

Referring to FIG. 2B, the latch unit 211 is composed of first to fourth NMOS transistors N1-N4 and a first latch L1.

The first NMOS transistor N1 is electrically connected between a node K1 and a ground node. To the gate of the first NMOS transistor N1 is applied a latch reset signal RST_CAM.

The first latch L1 is a latch element interposed between the node K1 and a node K2.

The second NMOS transistor N2 is electrically connected between the node K2 and a node K3. The third NMOS transistor N3 is electrically connected between the nodes K2 and K3. To the gate of the second NMOS transistor N2 is input the K'th (1≦K≦8) data bit DATLOAD<K>. To the gate of the third NMOS transistor N3 is input the [K+8]'th data bit DATLOAD_N<K>.

The fourth transistor N4 is electrically connected between the node N3 and the ground node. To the gate of the fourth transistor N4 is applied the first or second control signal BYTE<0> or BYTE<1>.

The latch unit 211 operates as follows.

When the nonvolatile memory device begins to be driven, the controller 160 outputs the latch reset signal RST_CAM in a logical high level to make the latch unit 211 reset.

Responding to the latch reset signal RST_CAM of a high logic level, the first NMOS transistor N1 is turned on to electronically connect the node K1 to the ground node. As the node K1 is connected to the ground node, the first latch L1 is reset.

Then the controller 160 loads address information on a defective column from the CAM cells and provides the first to sixteenth data bits DATLOAD<7:0> and DATLOAD_N<7:0> and the first and second control signals BYTE<Q> and BYTE<1> to the repair controller 170.

If the latch unit 211 belongs to the first redundancy info-latch block 210, the node K3 is electronically connected to the ground node when the first control signal BYTE<0> of a logic high level is applied to the gate of the fourth NMOS transistor N4.

Thus, the first latch L1 holds the k'th data bit DATLOAD<K> and the [K+8]'th data bit DATLOAD_N<K> when they are input thereto. This data held at the first latch L1 is the N'th (1≦N≦11) defective column address bit FAX<N> and the [N+11]'th defective column address bit FAX_N<N>.

Below the redundancy circuit for comparing the first to twenty-second defective column address bits FAX<12:2> and FAX_N<12:2>, which are stored at the latch units 211, with the first to twenty-second input address bits AX<12:2> and AX_N<12:2> is described.

FIG. 2C depicts the redundancy circuit of the address comparator shown in FIG. 2B.

Referring to FIG. 2C, the redundancy circuit 241 includes a first PMOS transistor P1, first to third inverters IN1-IN3, a first NAND gate NA1, a plurality of units of address comparators 241a, and a ninth NMOS transistor N9. Each unit of the address comparator 241a is formed of fifth to eighth NMOS transistors N5-N8.

The first PMOS transistor P1 is electrically connected between a power voltage terminal and a node K4. The gate of the first PMOS transistor P1 is coupled to an output terminal of the first inverter IN1.

The first inverter IN1 outputs an inverse signal of an output of the first NAND gate NA1. The first NAND gate NA1 receives a redundancy enable signal RDEN_N and a signal of a node K5.

The second inverter IN2 is electrically connected between a node K4 and the node K5. The third inverter IN3 inverts a voltage level of the node K5 and outputs an inverted signal. The output signal of the third inverter IN3 is the repair control signal REP_N.

The fifth and sixth NMOS transistors N5 and N6 are electrically connected in series between the node K4 and a node K6. The gate of the fifth NMOS transistor N5 receives the first input address bit AX<2>, while the gate of the sixth NMOS transistor N6 receives the first defective column address bit FAX<2>.

The seventh and eighth NMOS transistors N7 and N8 are electrically connected in series between the nodes K4 and K6. The gate of the seventh NMOS transistor N7 receives the twelfth input address bit AX_N<2>, while the gate of the eighth NMOS transistor N8 receives the twelfth defective column address bit FAX_N<2>.

By means of the units of address comparators 241a, the first to twenty-second defective column address bits FAX<12:2> and FAX_N<12:2> are respectively compared with the first to twenty-second input address bits AX<12:2> and AX_N<12:2>.

The ninth NMOS transistor N9 is electrically connected between a node K7 and the ground node. The redundancy check-enable signal REDCHKEN is applied to the gate of the ninth NMOS transistor N9.

The repair controller 170 according to an exemplary embodiment illustrated in FIGS. 2A to 2C may be designed to output the repair control signal REP_N at different timings depending upon an input order of input address bits.

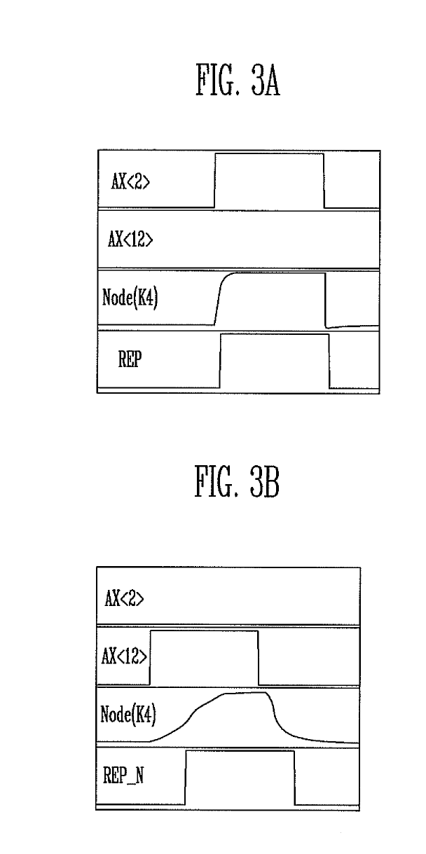

FIGS. 3A and 3B show sequential signal timings of address comparison operation according to the exemplary embodiment of FIG. 2A.

The timing diagram of FIG. 3A illustrates a case in which the first input address bit AX<2> agrees with its corresponding defective column address bit under the condition that the second to eleventh input address bits AX<12:3> (not the first input address bit AX<2>) match their corresponding defective column address bits. The timing diagram of FIG. 3B illustrates a case in which the eleventh input address bit AX<12> agrees with its corresponding defective column address bit under the condition that the first to tenth input address bits AX<11:2> match their corresponding defective column address bits.

Comparing the two cases of FIGS. 3A and 3B with each other, it can be seen that, if the first input address bit AX<2> as a preceding address bit agrees with the first defective column address bit FAX<2> later than other address bits, a voltage level of the node K4 is changed at almost the same time as the reception of the first input address bit AX<2> and the repair control signal REP_N is changed at the same time as the address reception.

Otherwise, if the eleventh input address bit AX<11> agrees with the eleventh defective column address bit FAX<11> later than the others as shown in FIG. 3B, a voltage level of the node K4 is unstable to thereby cause an output time of the repair control signal REP_N to be delayed.

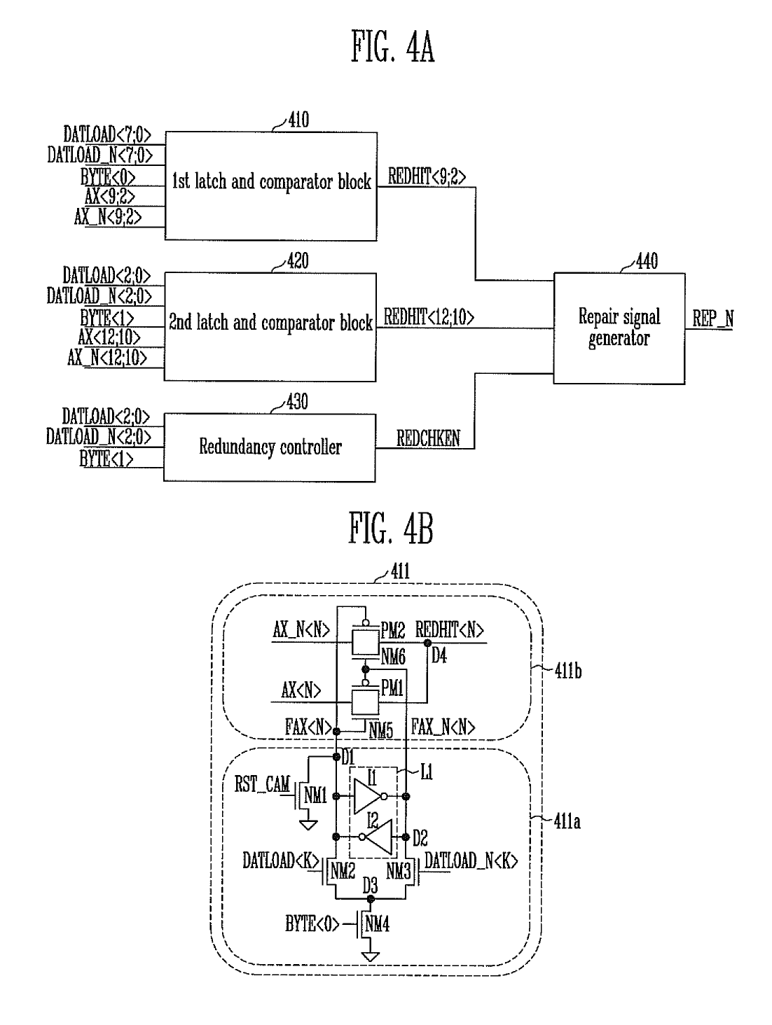

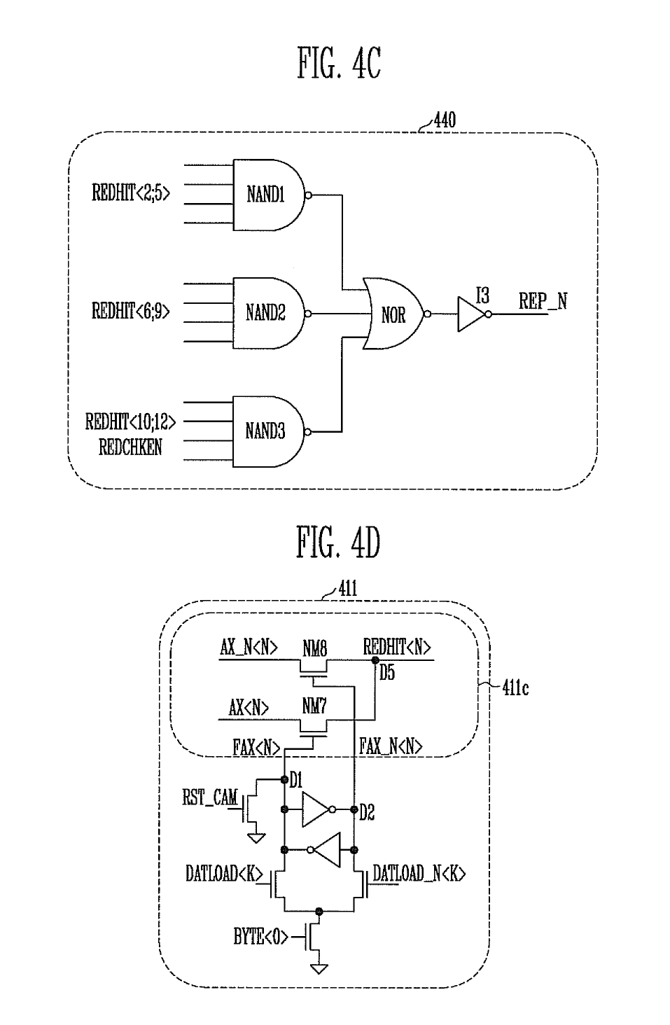

FIG. 4A depicts a repair controller according to another exemplary embodiment of the present invention.

Referring to FIG. 4A, the repair controller 170 includes first and second latch and comparator blocks 410 and 420, a redundancy controller 430, and a repair signal generator 440. These components of the repair controller 170, i.e., the first and second latch and comparator blocks 410 and 420, the redundancy controller 430, and the repair signal generator 440, may be arranged according to the defective column addresses.

The first latch and comparator block 410 functions to latch the first to eighth defective column address bits FAX<9:2> and the twelfth to nineteenth defective column address bits FAX_N<9:2> in accordance with the first to eighth data bits DATLOAD<7:0>, the ninth to sixteenth data bits DATLOAD_N<7:0>, and the first control signal BYTE<0>.

And, the first latch and comparator block 410 outputs first to eighth address matching signals REDHIT<9:2> based on a result of comparing the first to eighth input address bits AX<9:2> and the twelfth to nineteenth input address bits AX_N<9:2> with the first to eighth and twelfth to nineteenth defective column address bits FAX<9:2> and FAX_N<9:2>.

The second latch and comparator block 420 holds/latches the ninth to eleventh defective column address bits FAX<12:10> and the twentieth to twenty-second defective column address bits FAX_N<12:10> in accordance with the first to third data bits DATLOAD<2:0>, the ninth to eleventh data bits DATLOAD_N<2:0>, and the second control signal BYTE<1>, and outputs ninth to eleventh address matching signals REDHIT<12:10> in accordance with the ninth to eleventh defective column address bits FAX<12:10> and the twentieth to twenty-second defective column address bits FAX_N<12:10>.

The redundancy controller 430 generates the redundancy check-enable signal REDCHKEN in accordance with the first to third data bits DATLOAD<2:0>, the ninth to eleventh data bits DATLOAD_N<2:0>, and the second control signal BYTE<1>.

The repair signal generator 440 outputs the repair control signal REP_N in response to the first to eleventh address matching signals REDHIT<12:2> and the redundancy check-enable signal REDCHKEN.

The first and second latch and comparator blocks 410 and 420 may include latch comparators for holding/latching a defective column address bit. Each latch comparator may be configured as follows.

FIG. 4B depicts a latch comparator of the first latch and comparator block 410 shown in FIG. 4A. FIG. 4B shows a representative latch comparator among a plurality of latch comparators included in the first latch and comparator block 410.

Referring to FIG. 4B, the latch comparator 411 includes a comparator 411a and a latch circuit 411b.

The latch circuit 411b is formed of first to fourth NMOS transistors NM1-NM4, and first and second inverters I1 and I2. The comparator 411a is formed of fifth and sixth NMOS transistors NM5 and NM6, and first and second PMOS transistors PM1 and PM2.

The first NMOS transistor NM1 is electrically connected between a node D1 and a ground node. To the gate of the first NMOS transistor NM1 is applied a latch reset signal RST_CAM.

The first and second inverters I1 and I2 are coupled to form a first latch L1 between the node D1 and a node D2.

The second NMOS transistor NM2 is electrically connected between the node D1 and a node D3. The third NMOS transistor NM3 is electrically connected between the nodes D2 and D3. The K'th (1≦K≦8) data bit DATLOAD<K> is input to the gate of the second NMOS transistor NM2, while the [K+8]'th data bit DATLOAD_N<K> is input to the gate of the third NMOS transistor NM3.

The fourth NMOS transistor NM4 is electrically connected between the node D3 and the ground node. To the gate of the fourth NMOS transistor NM4 is applied the first control signal BYTE<0>.

The fifth NMOS transistor NM5 and the first PMOS transistor PM1 are interposed between the terminal of the N'th input address bit AX<N> and a node N4. The sixth NMOS transistor NM6 and the second PMOS transistor PM2 are interposed between the terminal of the [N+11]'th input address bit AX_N<N> and the node N4.

A pair of the fifth NMOS transistor NM5 and the first PMOS transistor PM1, and a pair of the sixth NMOS transistor NM6 and the second PMOS transistor PM2 form switch circuits respectively.

The gates of the first PMOS transistor PM1 and the sixth NMOS transistor NM6 are both coupled to the node D2. The gates of the second PMOS transistor PM2 and the fifth NMOS transistor NM5 are both coupled to the node D1.

A signal on the node D1 corresponds to the N'th defective column address bit FAX<N>. The [N+11]'th defective column address bit FAX_N<N> corresponds to a signal on the node D2.

From the node D4, the N'th address matching signal REDHIT<N> is output.

The latch comparator 411 operates as described hereinafter.

First, the node D1 is reset by the latch reset signal RST_CAM. Then, the first control signal BYTE<0>, the K'th data bit DATLOAD<K> and the [K+8]'th data bit DATLOAD_N<K> are input into the latch comparator 411. During this, if the K'th data bit DATLOAD<K> is laid on a logic high level, the [K+8]'th data bit DATLOAD_N<K> is set on a logic low level. And, when the first control signal BYTE<0> is applied thereto with a logic high level, the second and fourth NMOS transistors NM2 and NM4 are turned on.

Then, a low-level data bit is latched at the node D1 and a high-level data bit is latched at the node D2. That is, the N'th defective column address bit FAX<N> is ‘0’ and the [N+1]'th defective column address bit FAX_N<N> is ‘1’.

Accordingly, the second PMOS transistor PM2 and the sixth NMOS transistor NM6 are turned on while the first PMOS transistor PM1 and the fifth NMOS transistor NM5 are turned off. As a result, the input terminal of the [N+11]'th input address bit AX_N<N> is connected to the node D4.

Hereinafter is described two input cases: one is when the N'th input address bit AX<N> input is a ‘1’; and the other is when the N'th input address bit AX<N> input is a ‘0’.

First, if the N'th input address bit AX<N> is ‘1’, the [N+11]'th input address bit AX_N<N> becomes ‘0’. Thus, the N'th address matching signal REDHIT<N> is set on ‘0’. And, if the N'th input address bit AX<N> is ‘0’, the [N+11]'th input address bit AX_N<N> becomes ‘1’. Thus, the N'th address matching signal REDHIT<N> is set on ‘1’. That is, the N'th address matching signal REDHIT<N> is set on ‘1’ when the N'th input address bit AX<N> is identical with the N'th defective column address bit FAX<N>.

Further, the repair signal generator 440 for outputting the repair control signal REP_N according to the first to eleventh address matching signals REDHIT<12:2> that are provided from the latch comparator blocks 410 and 420 is formed as follows.

FIG. 4C depicts the repair signal generator shown in FIG. 4A.

Referring to FIG. 4C, the repair signal generator 440 includes first to third NAND gates NAND1-NAND3, a NOR gate NOR and a third inverter I3.

The first NAND gate NAND1 receives the first to fourth matching signals REDHIT<2:5> and the second NAND gate NAND2 receives the fifth to eighth address matching signals REDHIT<6:9>. The third NAND gate NAND3 receives the ninth to eleventh address matching signals REDHIT<10:12>, responding to the redundancy check-enable signal REDCHKEN.

The first to third NAND gates NAND1-NAND3 output logic low level signals only when their input signals are all in a logic high level. Thus, if the first to eleventh address matching signals REDHIT<12:2> are applied thereto all in a logic high level and the redundancy check-enable signal REDCHKEN is set on a logic high level, all of the first to third NAND gates NAND1-NAND3 output logic low level signals.

Output signals of the first to third NAND gates NAND1-NAND3 are all input into the NOR gate NOR. The NOR gate NOR outputs a logic high level signal only when all of its input signals are in a logic low level. An output signal of the NOR gate NOR is input into the third inverter I3. An output signal of the third inverter I3 becomes the repair control signal REP_N.

The first and second latch comparator blocks 410 and 420 and the redundancy controller 430 output the first to eleventh address matching signals REDHIT<12:2> and the redundancy check-enable signal REDCHKEN in logic high levels only when the defective column address bits are entirely identical with the input address bits. At this time, the repair signal generator 440 outputs the repair control signal REP_N with a logic low level. Responding to the repair control signal REP_N of a logic low level, it is determined that a current input address corresponds to the defective column address.

In the meantime, the latch comparator 411 may be formed as follows.

FIG. 4D depicts another exemplary embodiment of the latch comparator 411 belonging to the first latch comparator block 410 shown in FIG. 4A.

Referring to FIG. 4D, the latch comparator according to this exemplary embodiment is the same as that of FIG. 4B but for a comparator 411c. Thus, below only the comparator 411c is described.

The comparator 411c is formed of seventh and eighth NMOS transistors NM7 and NM8.

The seventh transistor NM7 is electrically connected between an input terminal of the N'th input address bit AX<N> and a node D5. The eighth NMOS transistor NM8 is electrically connected between an input terminal of the [N+11]'th input address bit AX_N<N> and the node D5.

The gate of the seventh NMOS transistor NM7 is coupled to a node D1 and the gate of the eighth NMOS transistor NM8 is coupled to a node D2.

The comparator 411c of FIG. 4D is the same as the comparator 411b of FIG. 4B in operation, but differs in configuration because it employs NMOS transistors for switching instead of a combination of PMOS and NMOS transistors.

In other embodiments, the nonvolatile memory device 100 may store the defective column address information by means of fuses, different from the scheme of using CAM cells. In such embodiments, the latch comparator 411 may be formed by replacing the latch circuit 411a with a fuse circuit that stores defective column addresses.

FIG. 4E depicts still another exemplary embodiment of the latch comparator belonging to the first latch comparator block 410 shown in FIG. 4A.

Referring to FIG. 4E, the N'th and [N+1]'th defective column address bits FAX<N> and FAX_N<N> are output from a fuse circuit 411d in which a defective column address is stored by fuse cutoff operation and then, in response, the comparator 411b outputs the N'th and [N+1]'th input address bits AX<N> and AX_N<N> to the node D4.

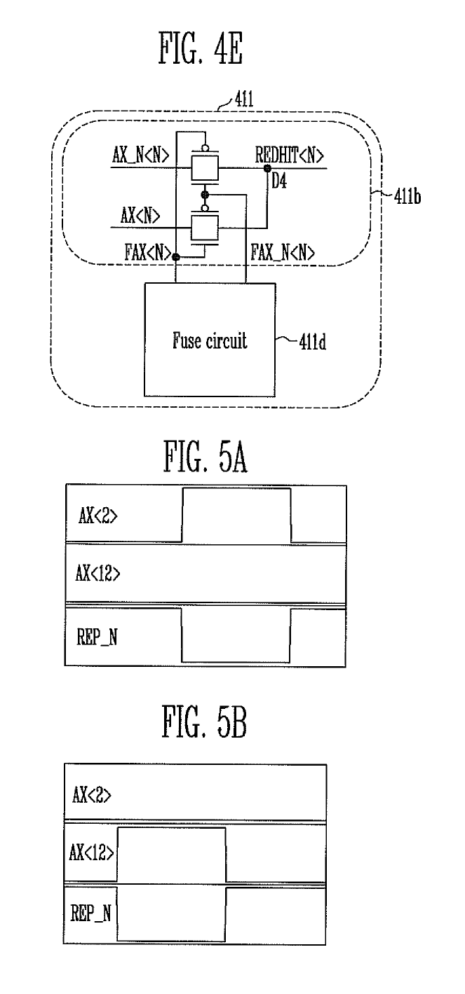

FIGS. 5A and 5B are timing diagrams showing output patterns of the repair control signal according to the exemplary embodiments shown in FIGS. 4A to 4D.

In more detail, the timing diagram of FIG. 5A illustrates the case when the first input address bit AX<2> agrees with its corresponding defective column address bit under the condition that the second to eleventh input address bits AX<12:3> (not the first input address bit AX<2>) match their corresponding defective column address bits. The timing diagram of FIG. 5B illustrates the case that the eleventh input address bit AX<12> agrees with its corresponding defective column address bit under the condition that the first to tenth input address bits AX<11:2> match their corresponding defective column address bits.

As depicted in FIGS. 5A and 5B, it can be seen that the repair controller 170, including the latch comparator and the repair signal generator, is able to provide the repair control signal REP_N without regard to an address matching order using an input sequence of an address.

Therefore, the efficiency for address matching can be enhanced in the nonvolatile memory device. Moreover, the nonvolatile memory device according to the exemplary embodiments of the present invention is advantageous in terms of size because a circuit area can be reduced due to a fewer number of elements used for generating the repair control signal REP_N.

The foregoing is illustrative of exemplary embodiments and is not to be construed as limiting thereof. Although a few exemplary embodiments have been described, those skilled in the art will readily appreciate that many modifications are possible in exemplary embodiments without materially departing from the novel teachings and advantages. Accordingly, all such modifications are intended to be included within the scope of this invention as defined in the claims.

What is claimed is:

1. A nonvolatile memory device comprising:
a memory cell array including main and redundant memory cells;
content addressable memory cells configured to store a defective column address corresponding to a defective memory cell among the main cells; and
a repair controller configured to compare the defective column address with an input address to generate a matching control signal and generate a redundancy check-enable signal when the defective column address is inputted as the input address and configured to generate a repair control signal in response to the matching control signal and the redundancy check-enable signal.

2. The nonvolatile memory device according to claim 1, wherein the repair controller comprises:
a plurality of address latches configured to store the defective column address;
a plurality of comparators configured to compare the defective column address and the input address to generate the matching control signal and the redundancy check-enable signal; and
a repair signal generator configured to generate the repair control signal in response to the matching control signal and the redundancy check-enable signal.

3. The nonvolatile memory device according to claim 2, wherein each address latch comprises a plurality of latch units configured to store the defective column address by bit, and each comparator comprises a plurality of comparator units configured to output the matching control signal by comparing the input address with the defective column address provided respectively from the latch units.

4. The nonvolatile memory device according to claim 3, wherein each comparator unit outputs the matching control signal with a first logic level if the defective column address of the latch unit has the same logic level as the input address.

5. The nonvolatile memory device according to claim 3, wherein each comparator unit comprises first and second switches configured to selectively output the input address and an inversion signal of the input address as the matching control signal according to the defective column address of the latch unit.

6. The nonvolatile memory device according to claim 4, wherein the repair signal generator outputs the repair control signal, which indicates that the input address is the defective column address, if the matching control signal and the redundancy check-enable signal are the first logic level.

7. The nonvolatile memory device according to claim 6, wherein the repair signal generator comprises:
one or more logical combination gates configured to conduct a NAND operation on the matching control signal and the redundancy check-enable signal; and
a logical combination circuit configured to logically combine output signals of the logical combination gates to generate the repair control signal.

8. The nonvolatile memory device according to claim 7, wherein the logical combination circuit comprises:
a NOR gate configured to conduct a NOR operation on the output signals of the logical combination gates; and
an inverter configured to output the repair control signal from an output signal of the NOR gate.

9. The nonvolatile memory device according to claim 1, wherein the main or redundant cells are selected in response to the repair control signal.

10. A nonvolatile memory device comprising:
a memory cell array comprising main and redundant cells;
a fuse circuit block configured to store a defective column address that is assigned to a defective cell of the main cells;
a plurality of comparators configured to compare the defective column address with an input address inputted by an operation command, and configured to output a matching control signal corresponding to a compared result and output a redundancy check-enable signal indicating that the defective column address is inputted as the input address; and
a repair signal generator configured to output a repair control signal in response to the matching control signal and the redundancy check-enable signal.

11. The nonvolatile memory device according to claim 10, wherein the comparator outputs the matching control signal with a first logic level if the defective column address has the same logic level as the input address.

12. The nonvolatile memory device according to claim 10, wherein the comparator comprises first and second switches configured to selectively output the input address and an inversion signal of the input address as the matching control signal according to the defective column address.

13. The nonvolatile memory device according to claim 11, wherein the repair signal generator outputs the repair control signal, which indicates that the input address is the defective column address, if the matching control signal and the redundancy check-enable signal are the first logic level.

14. The nonvolatile memory device according to claim 13, wherein the repair signal generator comprises:
one or more logical combination gates configured to conduct a NAND operation on the matching control signal and the redundancy check-enable signal; and
a logical combination circuit configured to logically combine output signals of the logical combination gates to generate the repair control signal.

15. The nonvolatile memory device according to claim 14, wherein the logical combination circuit comprises:
a NOR gate configured to conduct a NOR operation on the output signals of the logical combination gates; and
an inverter configured to output the repair control signal from an output signal of the NOR gate.
